(19) United States
(12) Patent Application Publication
(10) Pub. No.: US 2008/0130699 A1
(43) Pub. Date: Jun. 5, 2008

(54) CONTENT SELECTION USING SPEECH RECOGNITION

(75) Inventors: Changxue C. Ma, Barrington, IL (US); Yan M. Cheng, Inverness, IL (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 11/566,832

(22) Filed: Dec. 5, 2006

(51) Int. Cl. H01S 5/00

(52) U.S. Cl. 372/50.12

(57) ABSTRACT

Disclosed are a method and wireless device for selecting a content file using speech recognition. The method includes establishing a set of tagged text items wherein each tagged text item is uniquely associated with one content file of the set of content files. At least one audible utterance (226) is received (804) from a user. A phoneme lattice (302) is generated (808) based on the audible utterance (226). A phoneme lattice statistical model is generated (810) based on the phoneme lattice (302). A score is assigned (1008) to the tagged text items based on probabilistic estimates in the phoneme lattice statistical model. A list of high scoring tagged text items is presented (1014) so that a selection of a content file may be made. A word lattice (402) and a word lattice statistical model are also used in some embodiments

### FIELD OF THE INVENTION

The present invention generally relates to the field of speech recognition systems, and more particularly relates to speech recognition for content searching within a wireless communication device.

### BACKGROUND OF THE INVENTION

With the advent of pagers and mobile phones the wireless service industry has grown into a multi-billion dollar industry. Recently, speech recognition has enjoyed success in the wireless service industry. Speech recognition is used for a variety of applications and services. For example, a wireless service subscriber can be provided with a speed-dial feature whereby the subscriber speaks the name of a recipient of a call into the wireless device. The recipient's name is recognized using speech recognition and a call is initiated between the subscriber and the recipient. In another example, caller information (411) can utilize speech recognition to recognize the name of a recipient to whom a subscriber is attempting to place a call.

Another use for speech recognition in a wireless device is information retrieval. For example, content files such as an audio file can be tagged with voice data, which is used by retrieval mechanism to identify the content file. However, current speech recognition systems are incapable of efficiently performing information retrieval at a wireless device. Many content files within a wireless device include limited text. For example, an audio file may only have a title associated with it. This text is very short and can include spelling irregularities leading to out-of-vocabulary words.

Additionally some speech recognition systems utilize keyword spotting techniques to establish a set of keywords for a query. Since the vocabulary of the task is open and often falls outside of the vocabulary dictionary, it is difficult to implement the keyword spotting technique where the keywords and anti-keywords have to be carefully chosen. Therefore, other speech recognition systems implement a language model during a dictation mode. However, training such a language model is challenging because the data is scarce and dynamical. Traditional spoken document retrieval is often similar to text querying. For example, the speech recognition system is used to generate text query terms from a spoken utterance. These text query terms are then used to query a set of files for locating the file desired by the user. If the wireless device includes numerous files, this process can be relatively long thereby consuming and wasting resources of the wireless device.

Therefore a need exists to overcome the problems with the prior art as discussed above.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present invention.

FIG. 1 is a block diagram illustrating a wireless communication system according to an embodiment of the present invention;

FIG. 2 is a block diagram illustrating a more detailed view of the speech responsive search engine of FIG. 1 according to an embodiment of the present invention;

FIG. 3 is a block diagram illustrating an exemplary phoneme lattice according to an embodiment of the present invention;

FIG. 4 is a block diagram illustrating an exemplary word lattice according to an embodiment of the present invention;

FIG. 5 is a block diagram illustrating a wireless device according to an embodiment of the present invention;

FIG. 6 is a block diagram illustrating a information processing system according to an embodiment of the present invention;

FIG. 7 is an operational flow diagram illustrating an exemplary process of creating indexing N-grams according to an embodiment of the present invention;

FIG. 8 is an operational flow diagram illustrating an exemplary process of querying a phoneme lattice using indexing N-grams according to an embodiment of the present invention;

FIG. 9 is an operational flow diagram illustrating an exemplary process of querying a word lattice using indexing N-grams according to an embodiment of the present invention;

FIG. 10 is an operational flow diagram illustrating an exemplary process of querying a phoneme lattice using text associated with indexing N-grams for retrieving content in a wireless device according to an embodiment of the present invention; and

FIG. 11 is an operational flow diagram illustrating another exemplary process of querying a phoneme lattice for retrieving content in a wireless device according to an embodiment of the present invention.

### DETAILED DESCRIPTION

As required, detailed embodiments of the present invention are disclosed herein; however, it is to be understood that the disclosed embodiments are merely examples of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

The terms “a” or “an”, as used herein, are defined as one or more than one. The term plurality, as used herein, is defined as two or more than two. The term another, as used herein, is defined as at least a second or more. The terms including and/or having, as used herein, are defined as comprising (i.e., open language). The term coupled, as used herein, is defined as connected, although not necessarily directly, and not necessarily mechanically.

The term wireless communication device is intended to broadly cover many different types of devices that can wirelessly receive signals, and optionally can wirelessly transmit signals, and may also operate in a wireless communication system. For example, and not for any limitation, a wireless communication device can include any one or a combination of the following: a cellular telephone, a mobile phone, a smartphone, a two-way radio, a two-way pager, a wireless messaging device, a laptop/computer, automotive gateway, residential gateway, and the like.

One of the advantages of the present invention of speech responsive searching is to retrieve content based on an audible utterance received from a user. For finding the best matches, the N-grams or word sets in index files are treated as queries and a phoneme lattice and/or word lattice is treated as a document to be searched. Repetitive appearance of phoneme sequence renders discriminative power in the present invention. A conditional lattice model is used to score the query on the phoneme level to identify top phrase choices. In a two stage approach, words are found based on the phoneme lattice and tagged text items are found based on word lattice. Top scoring tagged text items are then used by the user to identify the content desired by the user.

Wireless Communications System

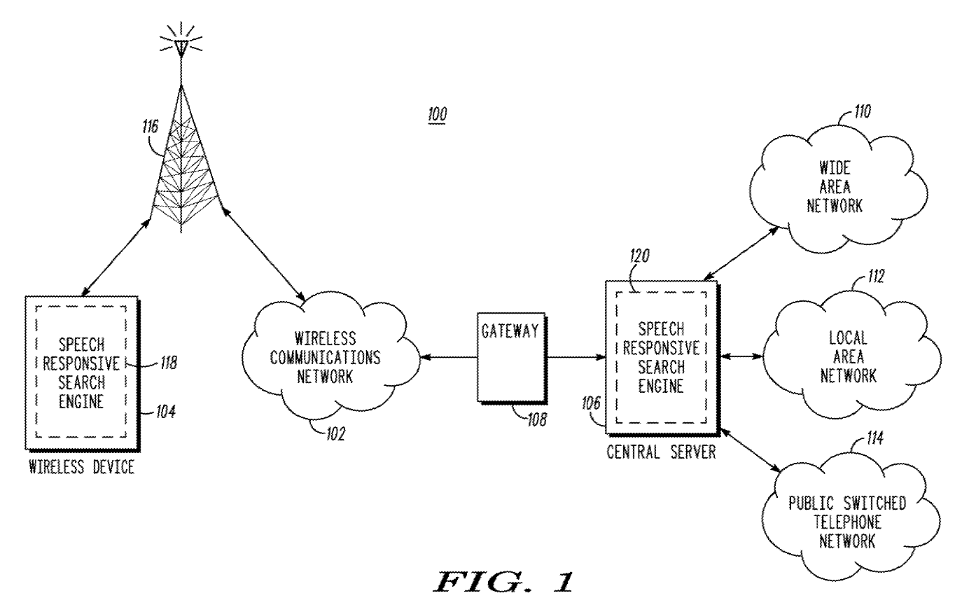

According to an embodiment of the present invention, as shown in FIG. 1, a wireless communications system 100 is illustrated. FIG. 1 shows a wireless communications network 102 that connects one or more wireless devices 104 with a central server 106 via a gateway 108. The wireless network 102 comprises a mobile phone network, a mobile text messaging device network, a pager network, or the like. Further, the communications standard of the wireless network 100 comprises Code Division Multiple Access (“CDMA”), Time Division Multiple Access (“TDMA”), Global System for Mobile Communications (“GSM”), General Packet Radio Service (“GPRS”), Frequency Division Multiple Access (“FDMA”), Orthogonal Frequency Division Multiplexing (“OFDM”), or the like. Additionally, the wireless communications network 102 also comprises text messaging standards, for example, Short Message Service (“SMS”), Enhanced Messaging Service (“EMS”), Multimedia Messaging Service (“MMS”), or the like.

The wireless communications network 102 supports any number of wireless devices 104. The support of the wireless communications network 102 includes support for mobile telephones, smart phones, text messaging devices, handheld computers, pagers, beepers, wireless communication cards, or the like. A smart phone is a combination of 1) a pocket PC, handheld PC, palm top PC, or Personal Digital Assistant (PDA), and 2) a mobile telephone. More generally, a smartphone can be a mobile telephone that has additional application processing capabilities. In one embodiment, wireless communication cards (not shown) reside within an information processing system (not shown).

Additionally, the wireless device 104 can also include an optional local wireless link (not shown) that allows the wireless device 104 to directly communicate with one or more wireless devices without using the wireless network 102. The local wireless link (not shown), for example, is provided by Mototalk for allowing PTT communications. The local wireless link (not shown), in another embodiment, is provided by Bluetooth, Infrared Data Access (IrDA) technologies or the like.

The central server 106 maintains and processes information for all wireless devices communicating on the wireless network 102. Additionally, the central server 106, in this example, communicatively couples the wireless device 104 to a wide area network 110, a local area network 112, and a public switched telephone network 114 through the wireless communications network 102. Each of these networks 110, 112, 114 has the capability of sending data, for example, a multimedia text message to the wireless device 104. The wireless communications system 100 also includes one or more base stations 116 each comprising a site station controller (not shown). In one embodiment, the wireless communications network 102 is capable of broadband wireless communications utilizing time division duplexing (“TDD”) as set forth, for example, by the IEEE 802.16e standard.

The wireless device 104, in one embodiment, includes a speech responsive search engine 118. The speech responsive search engine allows a user to speak an utterance into the wireless device 104 for retrieving content such as an audio file, a text file, a video file, an image file a multi-media file, or the like. The content can reside locally on the wireless device 104 or can reside on a separate system such as the central server 106 or on another system communicatively coupled to the wireless communications network 102. In one embodiment, the central server can include the speech responsive search engine 118 or can include one or more components of the speech responsive search engine 118. For example, the wireless device 104 can capture an audible utterance from a user and transmit the utterance to the central server 106 for further processing. Alternatively, the wireless device 104 can perform a portion of the processing while the central server 106 further processes the utterance for content retrieval. The speech responsive search engine 118 is discussed in greater detail below.

Speech Responsive Search Engine

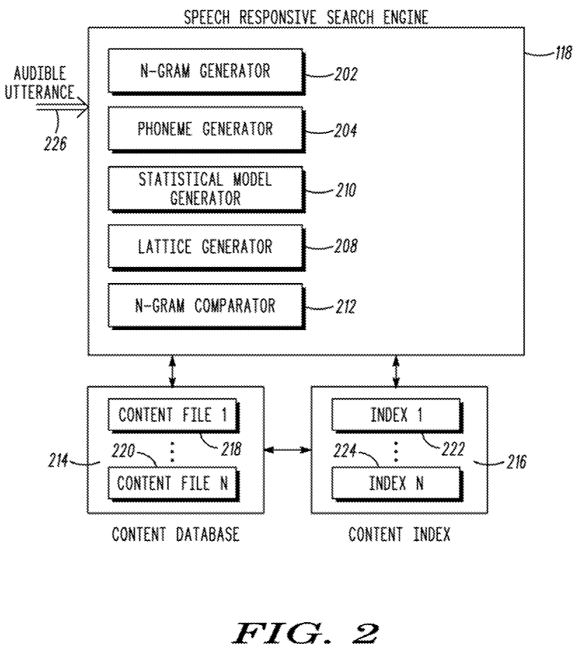

FIG. 2 is a block diagram illustrating a more detailed view of the speech responsive search engine 118. The speech search engine 118, in one embodiment, includes an N-gram generator 202, a phoneme generator 204, a lattice generator 208, a statistical model generator 210, and an N-gram comparator 212. The speech responsive search engine 118 is communicatively coupled to a content database 214 and a content index 216. The content database 214, in one embodiment, can reside within the wireless device 104, on the central server 106, a system communicatively coupled to the wireless communication network 102, and/or a system directly coupled to the wireless device 104.

The content database 214 comprises one or more content files 218, 220. The content file can be an audio file, a text file, a video file, an image file a multi-media file, or the like. The content index 216 includes one or more indexes 222, 224 associated with a respective content files 218, 220 in the content database 214. For example, if content file1 218 in the content database 214 is an audio file, then the index1 222 associated with the content file1 218 can be the title of the audio file. In other words the content files 218, 220 are associated with tagged text items, which can be for example, all song titles, or all song titles and book titles, or all tagged texts of all types of tagged text items. The tagged text items can be established by the user or may be obtained with the content files. For example, a user can select content files for which to create tagged text items, or the titles of songs may be obtained from a CD. Throughout this discussion “tagged text items”, “tagged text”, “content index files”, and “index files” can be used interchangeably.

When a user desires to retrieve a content file 218, 220 either residing on the wireless device 104 or on another system, the user speaks an audible utterance 226 into the wireless device 104. The wireless device 104 captures the audible utterance 226 via its microphone and audio circuits. For example, if a user desires to retrieve an MP3 file for a song, the user can speak the entire title of the song or part of the title. This utterance is then captured by the wireless device 104. The following discussion uses the example of an audio file (i.e. a song) being the content to be retrieved and the title of the song as being the index. However, this is only one example and is used for illustrative purposes only. As discussed above the content file can include text, audio, still images, and/or video. The index also can be lyrics of a song, specific words within a document, an element of an image, or any other information found within a file or associated with the file.

In one embodiment, the speech responsive search engine 118 uses automatic speech recognition to analyze the audible utterance received from the user. In general, an automatic speech recognition (“ASR”) system comprises Hidden Markov Models (“HMM”), grammar constraints, and dictionaries. If the constraint grammar is a phoneme loop, the ASR system uses the acoustic features converted from a user's speech signals and produces a phoneme lattice as an output. This phoneme loop grammar includes all the phonemes in a language. In one embodiment, an equal probability phoneme loop grammar is used for the ASR, but this grammar can have probabilities determined by language usage. However, if the grammar does have probabilities determined by language usage additional memory resources are required.

An ASR system can also be based on a word loop grammar. With the help of a pronunciation dictionary, the ASR system uses the phoneme-based HMM model and the acoustic features as inputs and produces a word lattice as an output. The word grammar can be based on all unique words used in the candidate indexing N-grams (needing updating as tagged texts were added), but alternatively could be based on a more general set of words. This grammar can be an equal probability word loop grammar, but could have probabilities determined by language usage.

The N-gram generator 202 analyzes the content index 216 to create one or more indexing N-grams associated with each tagged text item 222, 224 in the content index 216. In general, an N-gram is subsequence of n items from a given sequence of items. An N-gram can be a unigram (n=1) a bi-gram (n=2), a tri-gram (n=3), and the like. The items of indexing N-grams, for purposes of this document, are word sequences taken from the content index 216. The indexing N-grams are a class of word N-grams. For example, the word bi-grams for the sentence “this is a test sentence” are “this is”, “is a”, “a test”, “test sentence”. As can be been, each word bi-gram is a subsequence of two words from the sentence “this is a test sentence”. When a content index file 222, 224 includes the same words as other content index files, only one indexing bi-gram is created for the identical words. For example, consider the song titles “Let It Be” and “Let It Snow”. As can be seen both song titles include the bi-gram “Let It”. Therefore, only one bi-gram for “Let It” is created and indexes both song titles. In other words, one indexing unigram, indexing bi-gram, or the like can index two or more tagged text items 222, 224. The use of this data structure allows a user to say anything, so that a user does not have to remember an exact syntax. The indexing N-grams are also used as index terms to make content searching more efficient. Typical values for N as used for indexing N-grams are 2 or 3, although values of 1 or 4 or higher could be used. A value of 1 for N may substantially diminish the accuracy of the methods used in the embodiments taught herein, while numbers 4 and higher require ever increasing amounts of processing resources, with typically diminishing amounts of improvement.

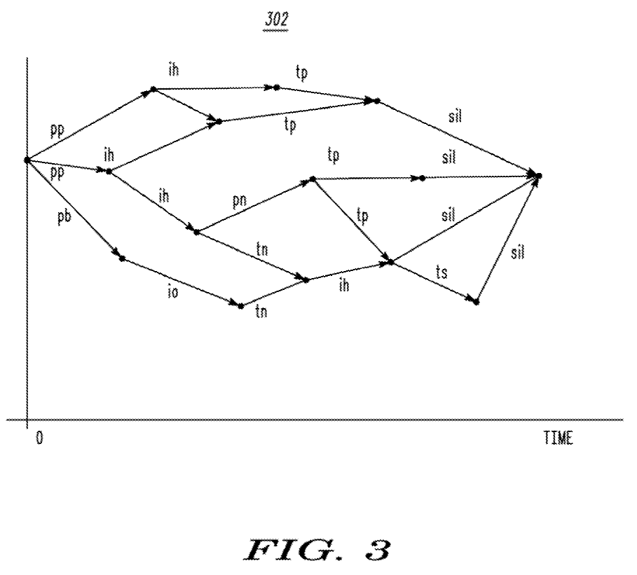

When an audible utterance 226 is captured from a user, the speech responsive search engine 118 converts the utterance 226 to acoustic feature vectors that are then stored. The lattice generator 208, based on phoneme loop grammar, creates a phoneme lattice associated with the audible utterance 226 from the feature vectors. An example of a phoneme lattice is shown in FIG. 3. The generation of a phoneme lattice is more efficient than conventional word recognition of an utterance on wireless devices.

The phoneme lattice 302 includes a plurality of phonemes recognized at a beginning and ending times within the utterance 416. Each phoneme can be associated with an acoustic score (e.g., a probabilistic score). Phonemes are units of a phonetic system of the relevant spoken language and are usually perceived to be single distinct sounds in the spoken language. In one embodiment, the creation of the phoneme lattice can be performed at the central server 106.

Once the phoneme lattice 302 associated with the audible utterance 226 is generated, the statistical model generator 210 generates a statistical model of the phonemes in the utterance, using the phoneme lattice 302, hereafter called the phoneme lattice statistical model. For example, the statistical model can be a table including a probabilistic estimate for each phoneme or a conditional probability of each phoneme given a preceding string of phonemes. In certain embodiments, the indexing N-grams created by the N-gram generator 202 are then evaluated using the phoneme lattice statistical model. In one embodiment, the phoneme generator 204 transcribes each indexing N-gram into a phoneme sequence using a pronunciation dictionary. For example, if the indexing N-gram is a unigram, the phoneme generator 204 transcribes the single word indexing unigram into its corresponding phoneme units. If the indexing N-gram is a bi-gram, the phoneme generator 204 transcribes the two words associated with the indexing bi-gram into their respective phoneme units. A pronunciation dictionary can be used to transcribe each word in the indexing N-grams into its corresponding phoneme sequence.

The probabilistic estimates that can be used in the phoneme lattice statistical model are phoneme conditional probabilistic estimates. In general, an N-gram conditional probability is used to determine a conditional probability of item X given previously seen item(s), i.e. p(item X|history item(s)). In other words, an N-gram conditional probability is used to determine the probability of an item occurring based on N−1 item strings before it. A bi-gram phoneme conditional probability can be expressed as p(X_{N}|X_{N-1}). For phonemes, if the first phoneme (X_{N-1}) of a pair of phonemes is known, then the bi-gram conditional probability expresses how likely a particular phoneme (X_{N}) will follow. A phoneme unigram “conditional” probabilistic estimate is not really a conditional probability, but simply the probabilistic estimate of X occurring in a given set of phonemes. Smoothing techniques can be used to generate an “improved” N-gram conditional probability. For example, a smoothed conditional tri-gram conditional probability P(x|yz) can be estimated from unigram and bi-gram conditional probabilities as p(x|y,z)=α*p(x|y,z)+β*p(x|y)+γ*p(x)+ε where α, β, γ and ε are given constants based on experiments and α+β+γ+ε=1.

In some embodiments, in which phoneme bi-gram conditional probability is used, the statistical model generator 210, given a phoneme lattice L determined from a user utterance, calculates the probabilistic estimate of a phoneme string p(x₁x₂ . . . x_{M}|L) associated with an indexing N-gram for a particular utterance for which a lattice L has been generated as: p(x₁x₂ . . . x_{M}|L)=p(x₁|L)p(x₂|x₁,L) . . . p(x_{M}|x_{M-1},L), where p(x₁x₂ . . . x_{M}|L) is the estimated probability that the indexing N-gram having the phoneme string x₁x₂ . . . x_{M} occurred in the utterance from which lattice L was generated; and is determined from the unigram [p(x₁|L)] and bi-gram [p(x_{M}|x_{M-1},L)] conditional probabilities of the phoneme lattice statistical model. The probability of occurrence, or probabilistic estimate of the phoneme string p(x₁x₂ . . . x_{M}|L) associated with an indexing N-gram for a particular utterance for which a lattice L has been generated can be determined more generally as p(x₁x₂ . . . x_{M}|L)=p(x₁|L)p(x₂|x₁,L)p(x₃|x₂,x₁,L) . . . p(x_{M}|x_{M-1}, . . . x_{M+1-N}, L), where p(x₁x₂ . . . x_{M}|L) is the estimated probability that the indexing N-gram having the phoneme string x₁x₂ . . . x_{M} occurred in the utterance from which lattice L was generated; and is determined from N gram (e.g., for tri-gram, N=3) conditional probabilities p(x₁|L), p(x₂|x₁,L), . . . , p(x_{M}|x_{M-1}, . . . x_{M+1-N},L) of the phoneme lattice statistical model. While the N used for the N gram conditional probabilities typically has a value of 2 or 3, other values, such as 1, 4 or even greater could be used. A value of 1 for N may substantially diminish the accuracy of the methods of the embodiments taught herein, while numbers 4 and higher require ever increasing amounts of processing resources, with typically diminishing amounts of improvement. The value M, which identifies how many phonemes are in an indexing N-gram, may typically be in the range of 5 to 20, but could be larger or smaller, and the range of M is significantly affected by the value of N used for the indexing N-grams. This probabilistic estimate, which is a number in the range from 0 to 1, is used to assign a score of the indexing N-gram. For example, the score may be identical to the probabilistic estimate or may be a linear function of the probabilistic estimate, or it may be the logarithm of probability divided by the number of terms.

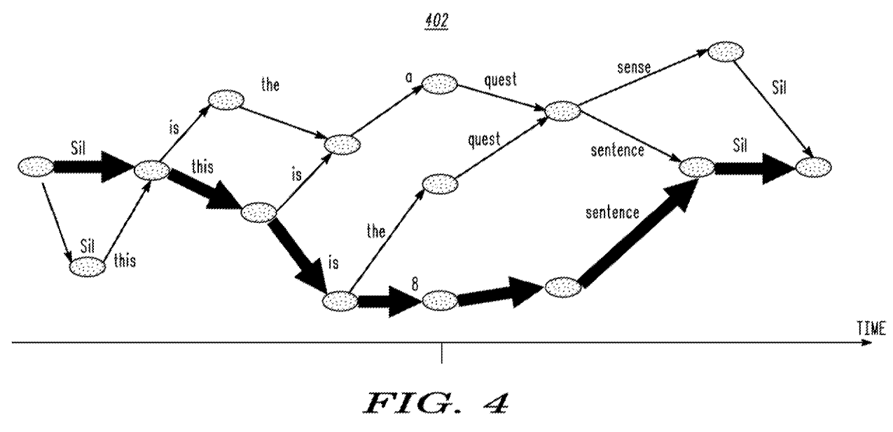

In certain embodiments, the N-gram comparator 212 of the speech responsive search engine 118 then determines a candidate list of indexing N-grams that have the highest scores (probabilistic estimates). For example, the top 50 indexing N-grams can be chosen based on their scores. In this embodiment a threshold is chosen to obtain a particular quantity of top scoring indexing N-grams. In other embodiments, a threshold could be chosen at an absolute level, and the subset may include differing quantities of indexing N-gram for different utterances. Other methods of determining a threshold could be used. It should be noted that the candidate list is not limited to 50 indexing N-grams. After the candidate list is created, the speech responsive search engine 118 in certain embodiments constructs a word loop grammar from the unique words in the candidate list. The acoustic features vectors associated with the audible utterance 226 are used, in some embodiments, by the lattice generator 208 in conjunction with the word loop grammar to generate a word lattice 402, an example of which is shown in FIG. 4.

The word lattice 402 comprises words recognized with beginning and ending times within the audible utterance 226. In one embodiment, each of the words within the word lattice 402 can be associated with an acoustic score. In certain embodiments, the statistical model generator 210 generates a word lattice statistical model similar to the phoneme lattice statistical model discussed above for the phoneme lattice 302. In one embodiment, an estimate of conditional probability such as P(word x|history words) for each word x in the word lattice 402 is created. The P(word x|history words) is the probability of word x given the preceding words (the history words). Typically, one history word may be used and each such conditional probability is referred to as a conditional word bi-gram probability.

In some embodiments, a subset of tagged text items (content index file) may be determined using the candidate list of (top-scoring) indexing N-grams discussed above. Only the tagged text items that include indexing N-grams from the candidate list are added to this subset. The remaining tagged text items in the whole tagged text set need not to be scored because they do not include any candidate indexing N-grams. In certain embodiments, the word string within each tagged text item in the subset of tagged text items is scored using probabilistic estimates determined from the word lattice statistical model. In other words, for the word lattice W determined from the audible utterance, the probabilistic estimate p(x₁x₂ . . . x₁|W) of the word string x₁x₂ . . . x_{M} of a subset tagged text item may be determined from the word N-gram conditional probabilities p(x₁|W), p(x₂|x₁,W), . . . , p(x_{M}|x_{M-1}, . . . x_{M+1-N},W) of the word lattice statistical model as: p(x₁|x₂ . . . x_{M}|W)=p(x₁|W)p(x₂|x₁W) . . . p(x_{M}|X_{M-1}, . . . x_{M+1-N},W). This probabilistic estimate is used to assign a score of the tagged text item. For example, the score may be identical to the probabilistic estimate or may be a linear function of the probabilistic estimate. The threshold may be a different type than that used to determine the top scoring indexing N-grams, and if it is the same type, it may be have a different value (i.e., while the top 5 tagged text items may be chosen for the subset of tagged text items, the top 30 indexing N-grams may be chosen for the subset of indexing N-grams) It will be appreciated that generating the subset of tagged text items is optional because if all tagged text items are scored, the score of those that do not include any of the candidate list of indexing N-grams will be the lowest. Using the subset typically saves processing resources.

In certain embodiments, the word string within each tagged text item in the subset of tagged text items is transcribed into a phoneme string that is scored using probabilistic estimates determined from the phoneme lattice statistical model, and several of the intervening processes described above are not performed. In particular, the generation of a word lattice and the determination of the word lattice statistical model need not be performed. In other words, the probabilistic estimate p(x₁x₂ . . . x_{M}|L) of the phoneme string x₁x₂ . . . x_{M} of each tagged text item in the subset of tagged text items may be determined from N-gram phoneme conditional probabilities p(x₁|L), p(x₂|x₁, L), . . . , p(x_{M}|x_{M-1}, . . . x_{M+1-N},L) of the phoneme lattice statistical model as: p(x₁x₂ . . . x_{M}|L)=p(x₁|L)p(x₂|x₁, L) . . . p(x_{M}|x_{M-1}, . . . x_{M+1-N},L), wherein the string x₁x₂ . . . x_{M} represents the entire string of phonemes that represent the tagged text item. The score may then be determined from the probabilistic estimate.

In certain embodiments, the word string within each tagged text item in the set of tagged text items is transcribed into a phoneme string that is scored using probabilistic estimates determined from the phoneme lattice statistical model, instead of a score for tagged text items being determined from a word lattice statistical model, and several intervening processes are not performed. In particular the evaluation of the indexing N-grams using the phoneme lattice statistical model, the determination of the candidate list of top scoring indexing N-grams, the determination of the subset of tagged text items, the generation of a word lattice, and the determination of the word lattice statistical model need not be performed. In other words, for the phoneme lattice L determined from the audible utterance, the probabilistic estimate p(x₁x₂ . . . x_{M}|L) of the phoneme string x₁x₂ . . . x_{M} of each tagged text item may be determined from phoneme conditional probabilities p(x₁|L), p(x₂|x₁,L), . . . , p(x_{M}|x_{M-1}, . . . x_{M+1-N},L) of the phoneme lattice statistical model as: p(x₁x₂ . . . x_{M}|L)=p(x₁|L)p(x₂ |x₁,L) . . . p(x_{M}|x_{M-1}, . . . x_{M+1-N},L), wherein the string x₁x₂ . . . . x_{M} represents the entire string of phonemes that represent the tagged text item. The score may then be determined from the probabilistic estimate. It will be appreciated that all tagged text items are scored, since no subset of tagged text items is determined in this embodiment. Another way of saying this is that this embodiment is similar to the previous one, but with the subset of tagged text items being identical with the set of tagged text items.

The speech responsive search engine can then present the tagged text files having the highest scores, using one or more output modalities such as a display and text to speech modality, from which the user may select one of the content files 218, 220 as the one referred to by the utterance In certain embodiments, for example when the score of the highest scored tagged text item differs from the scores of all other tagged text items by a sufficient margin, only the highest scored tagged text item is presented to the user and the content file associated with the highest scored tagged text item is presented. Alternatively, in this situation the content file associated with the highest scored tagged text item is presented without presenting the highest scored tagged text item, In certain embodiments, the top scoring tagged text items can be determined from the candidate list of top scoring N-grams. In certain embodiments, a word lattice is not generated. Also, all or part of the processing discussed above with respect to FIG. 2 can be performed by the central server 106 or another system coupled to the wireless device 104.

As can be seen, the present invention utilizes speech responsive searching to retrieve content based on an audible utterance received from a user. In the matching process, the indexing N-grams or word sets in index files are treated as queries and the phoneme lattice and/or word lattices are treated as documents to be searched. Repetitive appearance of phoneme sequence renders the correctness and then discriminative power of the phoneme sequence. A conditional lattice model is used to score the query on the phoneme level to identify top phrase choices. In a two stage approach, words are found based on a phoneme lattice and tagged text items are found based on a word lattice. Therefore the present invention overcomes the difficulties that ASR dictation faces on mobile devices. The present invention provides a fast and efficient speech responsive search engine that is easy to implement on mobile devices. The present invention allows a user to retrieve content with any word(s) or partial phrases.

Wireless Communication Device

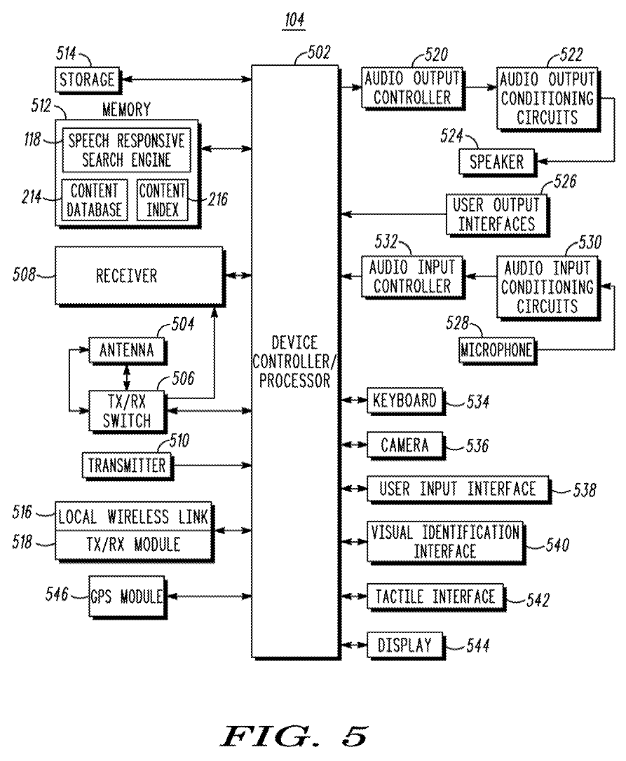

FIG. 5 is a block diagram illustrating a detailed view of the wireless communication device 104 according to an embodiment of the present invention. The wireless communication device 104 operates under the control of a device controller/processor 502, that controls the sending and receiving of wireless communication signals. In receive mode, the device controller 502 electrically couples an antenna 504 through a transmit/receive switch 506 to a receiver 508. The receiver 508 decodes the received signals and provides those decoded signals to the device controller 502.

In transmit mode, the device controller 502 electrically couples the antenna 504, through the transmit/receive switch 506, to a transmitter 510. The device controller 502 operates the transmitter and receiver according to instructions stored in the memory 512. These instructions include, for example, a neighbor cell measurement-scheduling algorithm. The memory 512, in one embodiment, also includes the speech responsive search engine 118 discussed above. It should be understood that the speech responsive search engine 118 shown in FIG. 5 also includes one or more of the components discussed in detail with respect to FIG. 2. These components have not been shown in FIG. 5 for simplicity. The memory 512, in one embodiment, also includes the content database 214 and the content index 216.

The wireless communication device 104, also includes non-volatile storage memory 514 for storing, for example, an application waiting to be executed (not shown) on the wireless communication device 104. The wireless communication device 104, in this example, also includes an optional local wireless link 516 that allows the wireless communication device 104 to directly communicate with another wireless device without using a wireless network (not shown). The optional local wireless link 516, for example, is provided by Bluetooth, Infrared Data Access (IrDA) technologies, or the like. The optional local wireless link 516 also includes a local wireless link transmit/receive module 518 that allows the wireless communication device 104 to directly communicate with another wireless communication device such as wireless communication devices communicatively coupled to personal computers, workstations, and the like.

The wireless communication device 104 of FIG. 5 further includes an audio output controller 520 that receives decoded audio output signals from the receiver 508 or the local wireless link transmit/receive module 518. The audio controller 520 sends the received decoded audio signals to the audio output conditioning circuits 522 that perform various conditioning functions. For example, the audio output conditioning circuits 522 may reduce noise or amplify the signal. A speaker 524 receives the conditioned audio signals and allows audio output for listening by a user. The audio output controller 520, audio output conditioning circuits 522, and the speaker 524 also allow for an audible alert to be generated notifying the user of a missed call, received messages, or the like. The wireless communication device 104 further includes additional user output interfaces 526, for example, a head phone jack (not shown) or a hands-free speaker (not shown).

The wireless communication device 104 also includes a microphone 528 for allowing a user to input audio signals into the wireless communication device 104. Sound waves are received by the microphone 528 and are converted into an electrical audio signal. Audio input conditioning circuits 530 receive the audio signal and perform various conditioning functions on the audio signal, for example, noise reduction. An audio input controller 532 receives the conditioned audio signal and sends a representation of the audio signal to the device controller 502.

The wireless communication device 104 also comprises a keyboard 534 for allowing a user to enter information into the wireless communication device 104. The wireless communication device 104 further comprises a camera 536 for allowing a user to capture still images or video images into memory 512. Furthermore, the wireless communication device 104 includes additional user input interfaces 538, for example, touch screen technology (not shown), a joystick (not shown), or a scroll wheel (not shown). In one embodiment, a peripheral interface (not shown) is also included for allowing the connection of a data cable to the wireless communication device 104. In one embodiment of the present invention, the connection of a data cable allows the wireless communication device 104 to be connected to a computer or a printer.

A visual notification (or indication) interface 540 is also included on the wireless communication device 104 for rendering a visual notification (or visual indication), for example, a sequence of colored lights on the display 544 or flashing one ore more LEDs (not shown), to the user of the wireless communication device 104. For example, a received multimedia message may include a sequence of colored lights to be displayed to the user as part of the message. Alternatively, the visual notification interface 540 can be used as an alert by displaying a sequence of colored lights or a single flashing light on the display 544 or LEDs (not shown) when the wireless communication device 104 receives a message, or the user missed a call.

The wireless communication device 104 also includes a tactile interface 542 for delivering a vibrating media component, tactile alert, or the like. For example, a multimedia message received by the wireless communication device 104, may include a video media component that provides a vibration during playback of the multimedia message. The tactile interface 542, in one embodiment, is used during a silent mode of the wireless communication device 104 to alert the user of an incoming call or message, missed call, or the like. The tactile interface 542 allows this vibration to occur, for example, through a vibrating motor or the like.

The wireless communication device 104 also includes a display 540 for displaying information to the user of the wireless communication device 104 and an optional Global Positioning System (GPS) module 546. The optional GPS module 546 determines the location and/or velocity information of the wireless communication device 104. This module 546 uses the GPS satellite system to determine the location and/or velocity of the wireless communication device 104. Alternative to the GPS module 546, the wireless communication device 104 may include alternative modules for determining the location and/or velocity of wireless communication device 104, for example, using cell tower triangulation and assisted GPS.

Information Processing System

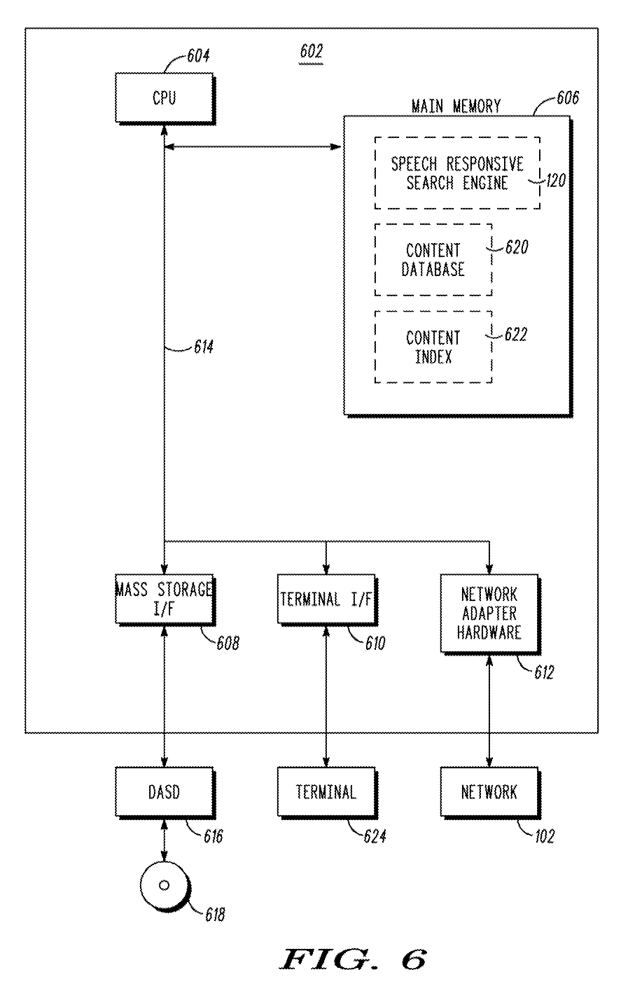

FIG. 6 is a block diagram illustrating a detailed view of the central server 106 according to an embodiment of the present invention. It should be noted that the following discussion is also applicable to any information processing coupled to the wireless device 104. The central server 106, in one embodiment, is based upon a suitably configured processing system adapted to implement the exemplary embodiment of the present invention. Any suitably configured processing system is similarly able to be used as the central server 106 by embodiments of the present invention, for example, a personal computer, workstation, or the like.

The central server 106 includes a computer 602. The computer 602 has a processor 604 that is communicatively connected to a main memory 606 (e.g., volatile memory), non-volatile storage interface 608, a terminal interface 610, a network adapter hardware 612, and a system bus 614 interconnects these system components. The non-volatile storage interface 608 is used to connect mass storage devices, such as data storage device 616, to the central server 106. One specific type of data storage device is a computer readable medium such as a CD drive, which may be used to store data to and read data from a CD or DVD 618 or floppy diskette (not shown). Another type of data storage device is a data storage device configured to support, for example, NTFS type file system operations.

The main memory 606 includes an optional speech responsive search engine 120, which includes one or more components discussed above with respect to FIG. 2. The main memory 606 can also optionally include a content database 620 and/or a content index 622 similar to the content database 214 and content index 216 discussed above with respect to FIG. 2. Although illustrated as concurrently resident in the main memory 606, it is clear that respective components of the main memory 606 are not required to be completely resident in the main memory 606 at all times or even at the same time.

In one embodiment, the central server 106 utilizes conventional virtual addressing mechanisms to allow programs to behave as if they have access to a large, single storage entity, referred to herein as a computer system memory, instead of access to multiple, smaller storage entities such as the main memory 606 and data storage device 416. Note that the term “computer system memory” is used herein to generically refer to the entire virtual memory of the central server 106.

Although only one CPU 604 is illustrated for computer 602, computer systems with multiple CPUs can be used equally effectively. Embodiments of the present invention further incorporate interfaces that each includes separate, fully programmed microprocessors that are used to off-load processing from the CPU 604. Terminal interface 610 is used to directly connect one or more terminals 624 to computer 602 to provide a user interface to the computer 602. These terminals 624, which are able to be non-intelligent or fully programmable workstations, are used to allow system administrators and users to communicate with the thin client. The terminal 624 is also able to consist of user interface and peripheral devices that are connected to computer 602 and controlled by terminal interface hardware included in the terminal I/F 610 that includes video adapters and interfaces for keyboards, pointing devices, and the like.

An operating system (not shown), according to an embodiment, can be included in the main memory and is a suitable multitasking operating system such as the Linux, UNIX, Windows XP, and Windows Server 2003 operating system. Embodiments of the present invention are able to use any other suitable operating system, or kernel, or other suitable control software. Some embodiments of the present invention utilize architectures, such as an object oriented framework mechanism, that allows instructions of the components of operating system (not shown) to be executed on any processor located within the client. The network adapter hardware 612 is used to provide an interface to the network 102. Embodiments of the present invention are able to be adapted to work with any data communications connections including present day analog and/or digital techniques or via a future networking mechanism.

Although the exemplary embodiments of the present invention are described in the context of a fully functional computer system, those skilled in the art will appreciate that embodiments are capable of being distributed as a program product via CD-ROM/DVD-ROM(RAM) 618, or other form of recordable media, or via any type of electronic transmission mechanism.

Process of Creating Indexing N-Grams

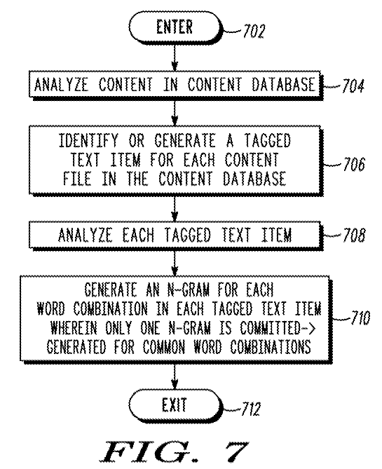

FIG. 7 is an operational diagram illustrating a process of creating indexing N-grams. The operational flow diagram of FIG. 7 begins at step 702 and flows directly to step 704. The speech responsive search engine 118, at step 704, analyzes content 218, 220 in a content database 214. A tagged text item (content index file) such as 222, 224 is identified or generated at step 706 for each content file 218, 220 in the content database 214, in some embodiments relying upon user input, thereby establishing a set of tagged text items. The speech responsive search engine 118, at step 708, analyzes each tagged text item 708. An N-gram, at step 710, is generated for each word combination in each tagged text item 222, 224, wherein only one N-gram is created for each unique word combination, thereby generating a set of indexing N-grams. Each N-gram is a sequential subset of at least one tagged text item. The control flow then exits at step 712.

Process of Retrieving Desired Content Using a Speech Responsive Search Engine

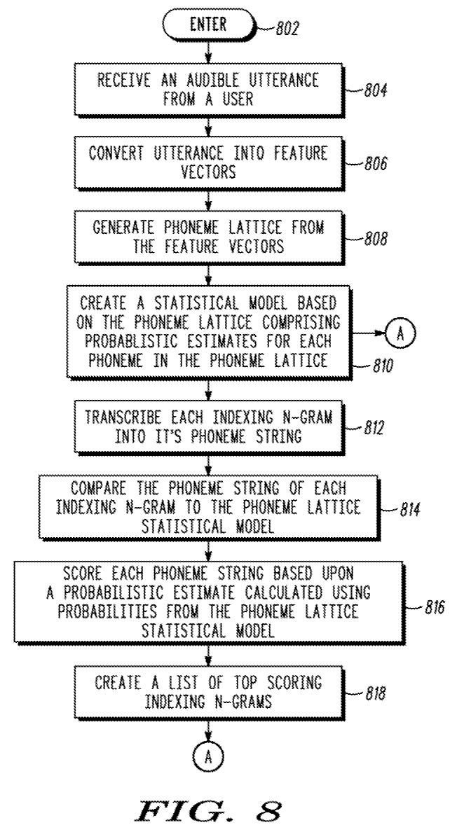

FIGS. 8 to 11 are operational flow diagrams illustrating a process of retrieving desired content using a speech responsive search engine. The operational flow diagram of FIG. 8 begins at step 802 and flows directly to step 804. The speech responsive search engine 118, at step 804, receives an audible utterance 226 from a user. For example, a user may desire to listen to a song and speaks the song's title.

The speech responsive search engine 118, at step 806, converts the utterance 226 into feature vectors and stores them. A phoneme lattice, at step 808, is generated from the feature vectors as discussed above. The speech responsive search engine 118, at step 810, creates a statistical model of the phonemes based on the phoneme lattice, a phoneme lattice statistical model. In one embodiment, the statistical model includes probabilistic estimates for each phoneme in the phoneme lattice. For example, the phoneme lattice statistical model can identify how likely a phoneme is to occur within the phoneme lattice. As discussed above conditional probabilities can also be included within the phoneme lattice statistical model. Each indexing N-gram, at step 812, is transcribed into its corresponding phoneme string.

Each phoneme string of an indexing N-gram, at step 814, is compared to the phoneme lattice statistical model to determine which probabilistic estimates from the phoneme lattice statistical estimates will be used for scoring the phoneme string. The speech responsive search engine 118, at step 816, scores each phoneme string of an indexing N-gram based on probabilistic estimates determined from the phoneme lattice statistical model. For example, if the indexing N-gram included the word set “let it”, this is transcribed into a phoneme string. The speech responsive search engine 118 then calculates the probabilistic estimate associated with “let it” from the statistical model and scores the phoneme string of the indexing N-gram accordingly. A candidate list of top scoring indexing N-grams, at step 818, is then generated.

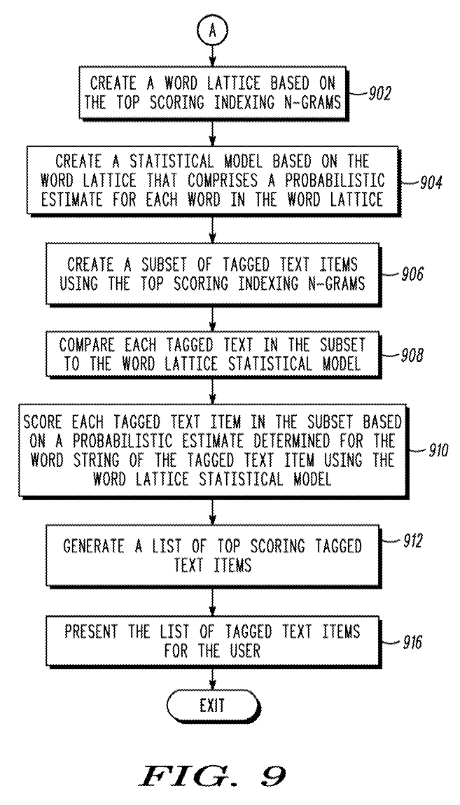

In certain embodiments, the control flows to entry point A of FIG. 9. A word lattice, at step 902, is generated from the top scoring indexing N-grams. The speech responsive search engine 118, at step, 904, creates a statistical model based on the word lattice at step 904. In one embodiment, the word lattice statistical model includes probabilistic estimates for each word in the word lattice. For example, the statistical model can identify how likely a word or set of words is to occur within the word lattice. As discussed above conditional probabilities can also be included within the word lattice statistical model. A subset of tagged text items is created at step 906 from the set of tagged text items 216 using the top scoring indexing N-grams.

Each tagged text item in the subset, at step 908, is compared to the word lattice statistical model of the words to determine which probabilistic estimates from the word lattice statistical model will be used for scoring the tagged text item. The speech responsive search engine 118, at step 910, scores each tagged text item in the subset based on a probabilistic estimate determined for the word string of the tagged text using the word lattice statistical model. For example, if the word N-gram included the word set “let it”, the speech responsive search engine 118 then identifies the probabilistic estimate associated with the phoneme string for “let it” in the statistical model and scores the word string accordingly. A list of top scoring tagged text items in the subset of tagged text items is then created at step 912. These top scoring tagged text items are then displayed to the user at step 916. The control flow then exits at step 918. The user may then select one of the tagged text items and the associated content files may be retrieved for the use of the user.

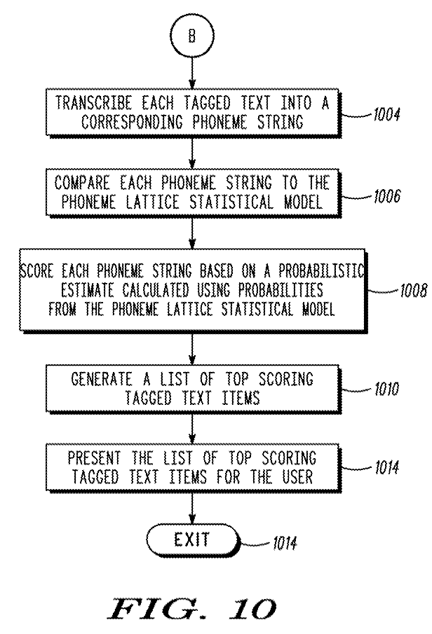

FIG. 10 is an operational flow diagram illustrating embodiments of retrieving desired content using a speech responsive search engine. The operational flow diagram of FIG. 10 flows from step 810 of FIG. 8 to step 1004. The speech responsive search engine 118, at step 1004, transcribes each tagged text item into a corresponding phoneme string. Each phoneme string of a tagged test item, at step 1006, is then compared to the phoneme lattice statistical model to determine which probabilistic estimates from the phoneme lattice statistical model will be used for scoring the phoneme strings of the tagged text. Each phoneme string of a tagged text item, at step 1008, is scored using probabilistic estimates from the phoneme lattice statistical model. The speech responsive search engine 118, at step 1010, generates a list of top scoring tagged text items. The list of top scoring tagged text items, at step 1014, is displayed to the user. The control flows at step 1016. The user may then select one of the tagged text items, and the content file(s) associated with it may then be retrieved for the user to use as desired.

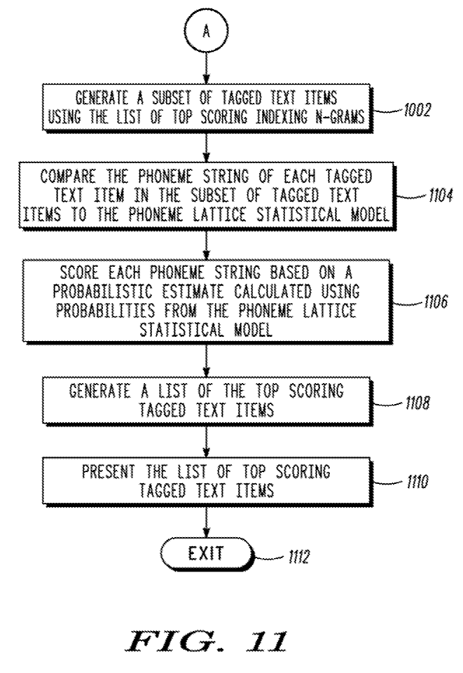

FIG. 11 is an operational flow diagram illustrating another process of retrieving desired content using a speech responsive search engine. The operational flow diagram of FIG. 10 flows from entry point A directly to step 1102. The speech responsive search engine 118, at step 1102, generates a tagged text subset from the set of tagged text items 216 using the candidate list of top scoring indexed N-grams. Each phoneme string of a tagged text item in the subset of tagged text items, at step 1104, is then compared to the phoneme lattice statistical model to determine which probabilities from the phoneme lattice statistical model will be used for scoring the phoneme strings of the tagged text. Each phoneme string of a tagged text item in the subset of tagged text items, at step 1106, is scored using probabilities from the phoneme lattice statistical model. The speech responsive search engine 118, at step 1108, generates a list of top scoring tagged text items in the tagged text subset. The list of top scoring tagged text items, at step 1110, is presented to the user. The control flows at step 1112. The user may then select one of the tagged text items, and the content file(s) associated with it may then be retrieved for the user to use as desired.

Non-Limiting Examples

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. A method used with a wireless communication device for selecting a content file from a set of content files using speech recognition, the method comprising:
establishing a set of tagged text items wherein each tagged text item is uniquely associated with one content file of the set of content files;
receiving at least one audible utterance from a user;
identifying a set of phonemes associated with the received audible utterance;
generating a phoneme lattice based on the identified set of phonemes;
generating a phoneme lattice statistical model based on the phoneme lattice;
assigning a score to each tagged text item in a subset of the set of tagged text items based on the phoneme lattice statistical model; and
presenting one or more of the tagged text items having a score that is above a threshold.

2. The method of claim 1, wherein the subset of the set of tagged text items is the entire set of tagged text items.

3. The method of claim 2, wherein the score assigned to each tagged text item is determined from an estimated probability, p(xₗx₂ . . . x_{M}|L)=p(x₁|L)p(x₂|x₁,L) . . . p(x_{M}|x_{M-1}, . . . x_{M+1-N},L), where p(x₁x₂ . . . x_{M}|L) is the estimated probability that a tagged text item having a phoneme string x₁x₂ . . . x_{M} occurred in the utterance from which phoneme lattice (L) was generated, and is determined from the probabilistic estimates p(x₁|L), p(x₂|x₁,L), . . . p(x_{M}|x_{M-1}, . . . x_{M+1-N},L) included in the phoneme lattice statistical model.

4. The method of claim 1, wherein the subset of the set of tagged text items is determined by:
generating a set of indexing N-grams from the set of tagged text items; wherein each indexing N-gram is a subset of at least one of the tagged text items.
assigning a score to each indexing N-gram in the set of indexing N-grams based on the phoneme lattice statistical model; and
including in the subset of the tagged text items those tagged text items that include indexing N-grams having an assigned score greater than a first threshold.

5. The method of claim 4, wherein each indexing N-gram in the set of indexing N-grams is unique and is a sequential subset of at least one tagged text item.

6. The method of claim 4, wherein assigning a score to each indexing N-gram in a set of indexing N-grams further comprises:
transcribing each indexing N-gram into a corresponding phoneme string; and
assigning a score to each indexing N-gram based on probabilistic estimates obtained from the phoneme lattice statistical model.

7. The method of claim 6, wherein the score assigned to each indexing N-gram is determined from an estimated probability, p(x₁x₂ . . . x_{N}|L)=p(x₁|L)p(x₂|x₁,L) . . . p(x_{N}|x_{N-1}, . . . x_{N-M},L), where p(x₁x₂ . . . x_{N}|L) is the estimated probability that an indexing N-gram having a phoneme string x₁x₂ . . . x_{N} occurred in the utterance from which phoneme lattice (L) was generated, and is determined from the probabilistic estimates p(x₁|L), p(x₂|x₁,L), . . . p(x_{M}|x_{M-1} . . . x_{M+1-N},L) included in the phoneme lattice statistical model.

8. A method used with a wireless communication device for selecting a content file from a set of content files, the method comprising:
establishing a set of tagged text items wherein each tagged text item is uniquely associated with one content file of the set of content files;
generating a set of indexing N-grams from the set of tagged text items;
receiving at least one audible utterance from a user;
generating a phoneme lattice based on the received at least one audible utterance;
generating a phoneme lattice statistical model based on the phoneme lattice;
assigning a score to each indexing N-gram in the set of indexing N-grams based on the phoneme lattice statistical model;
determining a subset of the set of indexing N-grams, wherein the indexing N-grams in the subset have an assigned score greater than a first threshold; generating a word lattice based on the subset of indexing N-grams;
generating a word lattice statistical model based on the word lattice;
assigning a score to each tagged text item in a subset of the set of tagged text items, wherein the subset comprises tagged test items that are associated with the subset of indexing N-grams, and wherein the score assigned to each tagged text item is based on the word lattice statistical model; and
presenting one or more of the tagged text items having scores above a second threshold.

9. The method of claim 8, wherein each indexing N-gram in the set of indexing N-grams is unique and is a sequential subset of at least one tagged text item.

10. The method of claim 8, wherein assigning a score to each indexing N-gram in a set of indexing N-grams further comprises:
transcribing each N-gram into a corresponding phoneme string; and
assigning a score to each indexing N-gram based on probabilistic estimates obtained from the phoneme lattice statistical model.

11. The method of claim 8, wherein the score assigned to each indexing N-gram is determined from an estimated probability, p(xₗx₂ . . . x₁|L)=p(x₁|L)p(x₂|x₁, L) . . . p(x_{M}|X_{M-1}, . . . x_{M+1-N},L), where p(x₁x₂ . . . x_{M}|L) is the estimated probability that an indexing N-gram having a phoneme string x₁x₂ . . . x_{M} occurred in the utterance from which phoneme lattice (L) was generated, and is determined from probabilistic estimates p(x₁|L), p(x₂|x₁,L), . . . , p(x_{M}|x_{M-1}, . . . x_{M+1-N},L) included in the phoneme lattice statistical model.

12. The method of claim 8, wherein the score assigned to each tagged text item is determined from an estimated probability p(x₁x₂ . . . x_{M}|W)=p(x₁|W)p(x₂|x₁,W) . . . p(x_{M}|x_{M-1}, . . . x_{M+1-N},W), where p(x₁x₂ . . . x_{M}|W) is the estimated probability that tagged text item having a word string x₁x₂ . . . x_{M} occurred in the utterance from which word lattice (W) was generated, and is determined from the probabilistic estimates p(xₗ|W), p(x₂|x₁, W), . . . , p(x_{M}|x_{M-1}, . . . x_{M+1-N},W) of the word lattice statistical model.

13. A wireless communication device comprising:
a memory;
a processor communicatively coupled to the memory; and
a speech responsive search engine communicatively coupled to the memory and the processor, the speech responsive search engine for:
establishing a set of tagged text items wherein each tagged text item is uniquely associated with one content file of the set of content files;
receiving at least one audible utterance from a user;
identifying a set of phonemes associated with the received audible utterance;
generating a phoneme lattice based on the identified set of phonemes;
creating a phoneme lattice statistical model based on the phoneme lattice;
assigning a score to each tagged text item in a subset of the set of tagged text items based on the phoneme lattice statistical model; and
presenting one or more of the tagged text items having a score that is above a threshold.

14. The wireless communication device of claim 13, wherein the subset of the set of tagged text items is the entire set of tagged text items.

15. The wireless communication device of claim 13, wherein the score assigned to each tagged text item is determined from an estimated probability, p(xₗx₂ . . . x₁|L)=p(x₁|L)p(x₂|x₁,L) . . . p(x_{M}|x_{M-1}, . . . x_{M+1-N},L), where p(x₁x₂ . . . x_{M}|L) is the estimated probability that a tagged text item having a phoneme string x₁x₂ . . . x_{M} occurred in the utterance from which phoneme lattice (L) was generated, and is determined from the probabilistic estimates p(x₁|L), p(x₂|x₁, L), . . . , p(x_{M}|x_{M-1}, . . . x_{M+1-N},L) included in the phoneme lattice statistical model.

16. The wireless communication device of claim 13, wherein the subset of the set of tagged text items is determined by:
generating a set of indexing N-grams from the set of tagged text items; wherein each indexing N-gram is a subset of at least one of the tagged text items.
assigning a score to each indexing N-gram in the set of indexing N-grams based on the phoneme lattice statistical model;
including in the subset of the tagged text items those tagged text items that include indexing N-grams having an assigned score greater than a first threshold.

17. The wireless communication device of claim 16, wherein each indexing N-gram in the set of indexing N-grams is unique and is a sequential subset of at least one tagged text item.

18. The wireless communication device of claim 16, wherein assigning a score to each indexing N-gram in a set of indexing N-grams further comprises:
transcribing each indexing N-gram into a corresponding phoneme string; and
assigning a score to each indexing N-gram based on probabilistic estimates obtained from the phoneme lattice statistical model.

19. The wireless communication device of claim 18, wherein the score assigned to each indexing N-gram is determined from an estimated probability, p(x₁x₂ . . . x_{N}|L)=p(x₁|L)p (x₂|x₁,L) . . . p(x_{N}|x_{N-1}, . . . x_{N-M},L), where p(x₁x₂ . . . x_{N}|L) is the estimated probability that an indexing N-gram having a phoneme string x₁x₂ . . . x_{N} occurred in the utterance from which phoneme lattice (L) was generated, and is determined from the probabilistic estimates p(x₁|L), p(x₂|x₁,L), . . . p(x_{M}|x_{M-1} . . . x_{M+1-N},L) included in the phoneme lattice statistical model.

20. The wireless communication device of claim 18, wherein the score assigned to each tagged text item in the subset of tagged text items is determined from an estimated probability, p(xₗx₂ . . . x_{M}|L)=p(x₁|L)p(x₂|x₁L) . . . p(x_{M}|x_{M-1}, . . . x_{M+1-N},L), where p(x₁x₂ . . . x_{M}|L) is the estimated probability that a tagged text item having a phoneme string x₁x₂ . . . x_{M} occurred in the utterance from which phoneme lattice (L) was generated, and is determined from the probabilistic estimates p(x₁|L), p(x₂|x₁,L), . . . , p(x_{M}|x_{M-1}, . . . x_{M+1-N},L) included in the phoneme lattice statistical model.
